(19) United States
(12) Patent Application Publication
(10) Pub. No.: US 2003/0199114 A1
(43) Pub. Date: Oct. 23, 2003

(54) Electro-optical device, method for fabricating the same, and electronic apparatus

(75) Inventor: Takefumi Fukagawa, Chino-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/351,547

(22) Filed: Jan. 27, 2003

(30) Foreign Application Priority Data
Mar. 8, 2002 (JP) 2002-064316

(51) Int. Cl. H01L 21/00

(52) U.S. Cl. 438/29; 438/30

(57) ABSTRACT

The invention provides a liquid crystal device having a structure in which electrical conduction between substrates is maintained and the cell gap can be easily controlled. A liquid crystal device of the present invention can include a TFT array substrate and a counter substrate facing each other, and a liquid crystal is interposed between the substrates. A conductive layer is applied to a protrusion provided on the counter substrate to form an intersubstrate conductive part. By placing the intersubstrate conductive part inside a sealant, stable electrical conduction between the TFT array substrate and the counter substrate can be performed, and a predetermined cell gap is maintained.

### BACKGROUND OF THE INVENTION

1. Field of Invention

The present invention relates to electro-optical devices, methods for fabricating the same, and electronic apparatuses. More particularly, the invention relates to a substrate structure suitable for controlling the distance and electrical conduction between the substrates.

2. Description of Related Art

FIG. 13 shows an example of a conventional liquid crystal display device. The liquid crystal panel 100 includes a device substrate (TFT array substrate) 102 on which a plurality of data lines and scanning lines 101 are formed like a grid and on which switching elements including pixel electrodes, thin-film transistors (TFTs) for driving the pixel electrodes, and the like are arrayed in a matrix. Additionally, a counter substrate 104 is provided with a counter electrode 103 with the device substrate 102 and the counter electrode 104 being disposed with a predetermined distance therebetween. The device substrate 102 and the counter substrate 104 are bonded to each other by a sealant 105 so that their respective electrode-forming surfaces face each other. A liquid crystal 106 is enclosed in a region between the substrates delimited by the sealant 105, and spacers 107 are also placed in the region to maintain a predetermined distance between the substrate 102 and the substrate 104. A common electrode 108 is formed in a region other than the liquid crystal-filling region on the electrode-forming surface of the device substrate 102. A conductive part 109 composed of silver paste is placed on the common electrode 108 so that electrical conduction is performed between the device substrate 102 and the counter substrate 104. Polarizers 110 are attached to the outer surfaces of the device substrate 102 and the counter substrate 104.

Although not shown in the drawing, a data line drive IC which supplies data signals to the individual data lines and a scanning line drive IC for supplying scanning signals to the individual scanning lines 101 are mounted on a terminal region of the device substrate 102 extending further than the counter substrate 104.

In this example, a backlight unit 111 is further disposed on the lower surface of the device substrate 102 with a buffer 112 composed of silicone rubber or the like therebetween. The backlight unit 111 can include a linear fluorescent tube 113 for emitting light, a reflector 115 which reflects the light from the fluorescent tube 113 and guides it toward a light guide plate 114, a diffuser 116 which diffuses the light guided by the light guide plate 114 uniformly toward the liquid crystal panel 100, and a reflector 117 which reflects the light emitted from the light guide plate 114 in a direction opposite to the liquid crystal panel 100 toward the liquid crystal panel 100.

In order to fabricate such a liquid crystal display device, first, necessary electrode layers and drive circuit layers are formed on the device substrate 102 and the counter substrate 104 using a technique, such as photolithography. For example, the spacers 107 for maintaining a predetermined distance between the substrates are then scattered on the electrode-forming surface of the device substrate 102, and the sealant 105 for sealing the liquid crystal is disposed on the electrode-forming surface of the counter substrate 104.

Next, the device substrate 102 and the counter substrate 104 are bonded to each other, and the liquid crystal 106 is poured into the gap between the substrates from a port of the sealant 105. The port is then sealed by the sealant 105, and polarizers 110 are attached to the outer surfaces of the substrates. The liquid crystal panel 100 is thereby completed.

Finally, the backlight unit 111, and various boards for driving the unit are mounted on the liquid crystal panel 100, and the product is placed in a case. The liquid crystal display device is thereby completed.

### SUMMARY OF THE INVENTION

The conductive part 109 for performing electrical conduction between the upper and lower substrates is formed by hardening a conductive paste. In the conductive paste, for example, highly conductive metal powder, such as silver powder, and a conductive filler, and the like, are kneaded into a resin. In order to form the conductive part 109, for example, a predetermined amount of conductive paste is dripped by a dripping apparatus, such as a dispenser, to a predetermined position on the electrode-forming surface of the device substrate 102, and then the resin is hardened by an appropriate technique, such as heating or light irradiation.

Although such a conductive part 109 can be formed inexpensively, there are limitations in positional accuracy and quantitative accuracy when the conductive paste is dripped. A spot on which the paste is dispensed by the dispenser occupies, for example, an area of approximately 0.5 mm×0.5 mm, which is not suitable for narrower frames of recent liquid crystal devices. Furthermore, depending on the dripping conditions and hardening conditions of the conductive paste, the contact bonding density and contact bonding area may be varied, resulting in a fluctuating electrical resistance. In addition, since the conductive paste is exposed to air, the electrical resistance also changes with time, exhibiting poor durability.

In order to solve the problems described above, a construction has been proposed in which conductive particles composed of resin particles coated with metal films, metal particles, or the like are directly dispersed into a sealant to form a conductive part. However, in such a construction, the electrical resistance of the conductive part varies due to the aggregation and dispersibility of the conductive particles or metal particles, and the electrical conductivity of the conductive part also varies with the contact bonding density between the sealant and the substrates, and thus the conductive part lacks in reliability.

The present invention has been achieved to solve the problems described above. It is an object of the present invention to provide an electro-optical device including an intersubstrate conductive part which can stably maintain electrical conduction between the substrates, a method for fabricating the same, and an electronic apparatus including the electro-optical device.

One aspect of the present invention provides an electro-optical device including a pair of substrates facing each other and an electro-optical material interposed between the pair of substrates, wherein a conductive section is provided on the inner surface of each of the pair of substrates, an intersubstrate conductive part comprising a protrusion coated with a conductive layer is provided on one of the pair of substrates, and the conductive sections of the individual substrates are connected to each other through the intersubstrate conductive part. The conductive section provided on the inner surface of each of the pair of substrates can include electrodes and interconnecting lines.

In such a construction of the present invention, electrical conduction between the conductive sections of the individual substrates can be reliably maintained by the conductive layer having reliable conductivity. Furthermore, since the conditions for connection between the conductive layer and the substrate can be controlled, it is possible to prevent fluctuation of electrical characteristics, such as electrical resistance, due to a change in connecting conditions, and stable electrical conduction between the substrates is ensured.

Another aspect of the present invention provides an electro-optical device including a pair of substrates facing each other and an electro-optical material interposed between the pair of substrates. Further, a conductive section can be provided on the inner surface of each of the pair of substrates, a protrusion can be provided on one of the pairs of substrates, the protrusion maintaining a predetermined distance between the pair of substrates, and the conductive sections of the individual substrates are electrically connected to each other through an inter substrate conductive part comprising the protrusion coated with a conductive layer.

In such a construction of the present invention, electrical conduction between the conductive sections of the individual substrates can be reliably and stably maintained, and it is also possible to maintain a predetermined distance between the substrates by the sum of the height of the protrusion and the thickness of the conductive layer. In other words, if the sum of the height of the protrusion and the thickness of the conductive layer is preliminarily adjusted to a predetermined value corresponding to the distance between the substrates, a gap between the substrates is inevitably determined, and thus the gap control is facilitated. That is, since the intersubstrate conductive part of the present invention also serves as a conventional spacer, the gap control between the substrates can be performed rationally. Preferably, the protrusion of the intersubstrate conductive part can be formed of at least one layer material constituting one of the substrates.

In such a construction, when the protrusion is formed on the substrate, it is not necessary to prepare a material that is different form the material for the substrate, and an increase in fabrication costs can be prevented. Since the protrusion can be formed using the material constituting the device substrate or the counter substrate, the formation can be performed by only slightly changing the usual fabrication process conditions.

Preferably, the protrusion is composed of a resin material, such as an acrylic film or a polyimide film. By using such a photosensitive thermosetting resin, a protrusion having a desired shape and thickness can be easily formed on the substrate by photolithography or the like.

Preferably, the conductive layer of the intersubstrate conductive part is composed of a metal film. The metal film can provide much stabler conductivity and can stabilize the electrical characteristics between the substrates. Since the metal film can be easily and inexpensively applied to the surface of the protrusion with a predetermined thickness by various film-forming techniques, the costs of the electro-optical device can be also reduced.

Preferably, the conductive layer of the intersubstrate conductive part is composed of a transparent conductive film. By forming the protrusion also using a transparent material, even if the intersubstrate conductive part is formed in any region of the electro-optical device, the light transmittance of the electro-optical device is not decreased. Furthermore, such a construction, it is possible to form the conductive layer of the intersubstrate conductive part simultaneously when transparent electrodes are formed on the substrates, and the fabrication process can be simplified.

A liquid crystal may be used as the electro-optical material. In such a construction, it is possible to produce a liquid crystal display device in which electrical conductivity between the substrates is stably maintained, and the cell gap is reliably controlled.

The intersubstrate conductive part may be provided only in an periphery outside the image-display region of each substrate. In such a construction, since the structure within the image-display region, i.e., the pixel region, is the same as that in the conventional degree of design freedom of the pixel pattern as that in the conventional device, is ensured, and electrical conduction between the substrates can also be maintained reliably.

The intersubstrate conductive part may be placed within a sealing section for sealing the liquid crystal. In such a construction, the intersubstrate conductive part can be more strongly brought into contact with the substrates, stabler electrical conduction can be maintained, and the mechanical strength can also be improved. Furthermore, since the intersubstrate conductive part is protected by the sealing section, the intersubstrate conductive part is not in contact with air, and a change in electrical resistance due to oxidation of the conductive layer, etc., can be reduced, and thus an electro-optical device with satisfactory durability can be produced. Moreover, in such a construction, it is not necessary to arrange a conductive part-forming space outside the image-display region of the electro-optical device, and the frame of the electro-optical device can be narrowed.

In such a construction, since the intersubstrate conductive part functions as a spacer in the sealant, spacers which have been mixed into the sealant or the electro-optical material are no longer required, and thus the fabrication process is simplified.

Another aspect of the present invention provides a method for fabricating an electro-optical device including an electro-optical material interposed between a pair of substrates facing each other. The method can include the steps of forming a protrusion on one of the substrates and forming a conductive layer on the protrusion to produce an intersubstrate conductive part.

In this method, after the protrusion is formed at a predetermined position, the conductive layer in which electrical conductivity does not change can be reliably formed on the surface of the protrusion by controlling the formation conditions appropriately. Therefore, the intersubstrate conductive part having a constant electrical conductivity and accurate electrical characteristics can be formed at a predetermined position.

Additionally, in this method, a step of dripping and hardening a conductive paste can be eliminated, and all of the fabrication steps can be performed by film-forming techniques only. Therefore, fabrication costs can be reduced because of the simplification of the fabrication process and machinery.

In the method for fabricating the electro-optical device of the present invention, preferably, the protrusion of the intersubstrate conductive part is integrally molded with the substrate. In such a method, it is not necessary to newly provide a step of forming the protrusion of the intersubstrate conductive part.

In the method for fabricating the electro-optical device of the present invention, preferably, the protrusion of the intersubstrate conductive part is formed by photolithography. In such a method, the protrusion having a desired shape and thickness can be easily formed on the substrate, and the intersubstrate conductive part can also be easily formed, for example, by a slight change in the process when another element or the like is formed on the substrate.

Another aspect of the present invention provides an electronic apparatus including the electro-optical device of the present invention described above.

In accordance with the present invention, it is possible to produce an electro-optical device provided with a display region having high display quality since the electro-optical device of the present invention is provided.

### BRIEF DESCRIPTION OF THE DRAWINGS

The invention will be described with reference to the accompanying drawings, wherein like numerals reference like elements, and wherein:

FIG. 1 is an equivalent circuit diagram showing various elements, lines, etc., in a plurality of pixels constituting the image display region of a liquid crystal device in a first embodiment of the present invention;

FIG. 2 is a plan view showing a plurality of adjoining pixels in a TFT array substrate of the liquid crystal device in the first embodiment of the present invention;

FIG. 3 is a plan view of a counter substrate of the liquid crystal device in the first embodiment of the present invention;

FIG. 4 is a sectional view taken along the line A-A′ of FIGS. 2 and 3;

FIGS. 5(1) to (5) are sectional views illustrating fabrication steps of a TFT array substrate of the liquid crystal device in the first embodiment of the present invention;

FIG. 6 is a plan view showing the overall structure of the liquid crystal device in the first embodiment of the present invention;

FIG. 7 is a sectional view taken along the line B-B′ of FIG. 6;

FIG. 8 is a plan view showing the overall structure of a liquid crystal device in a second embodiment of the present invention;

FIG. 9 is a sectional view taken along the line C-C′ of FIG. 8;

FIG. 10 is a perspective view showing an example of an electronic apparatus using a liquid crystal device of the present invention;

FIG. 11 is a perspective view showing another example of an electronic apparatus using a liquid crystal device of the present invention;

FIG. 12 is a perspective view showing still another example of an electronic apparatus using a liquid crystal device of the present invention; and

FIG. 13 is a sectional view showing an example of a conventional liquid crystal display device.

### DETAILED DESCRIPTION OF PREFERRED EMBODIMENTS

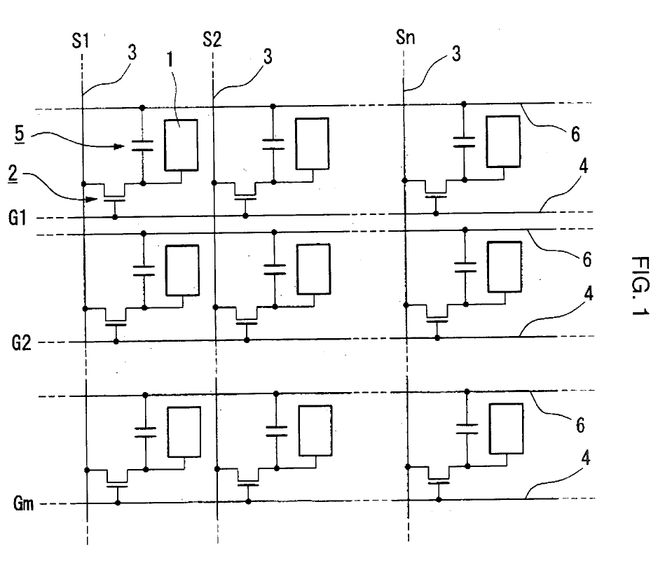

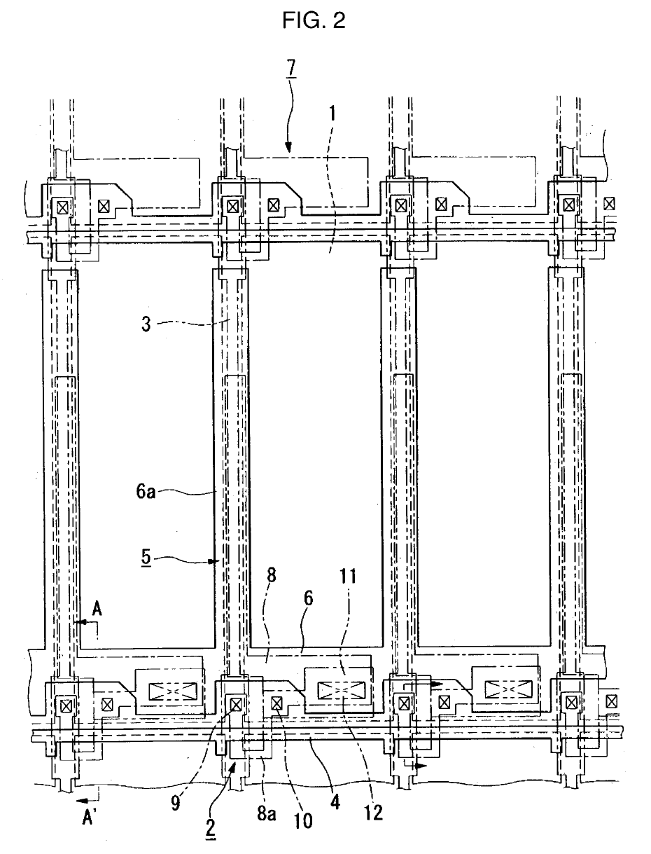

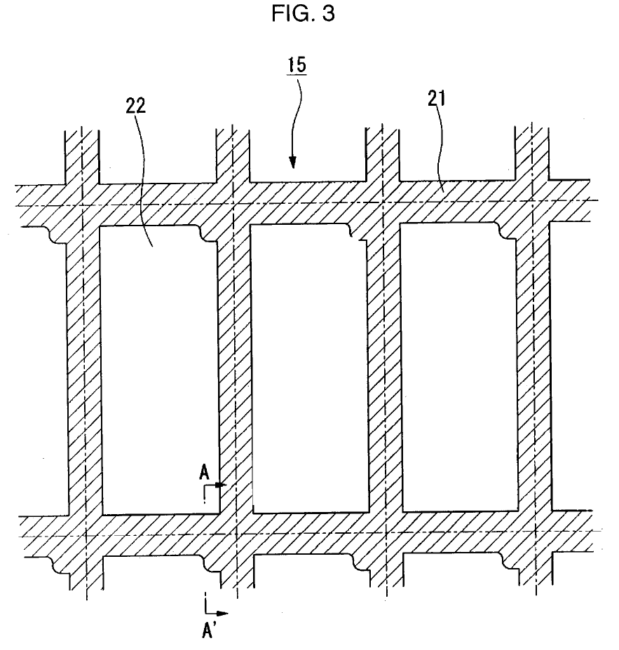

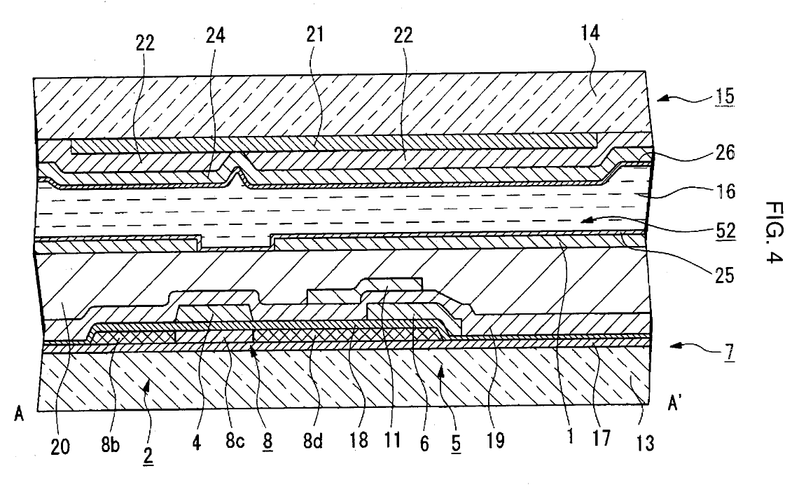

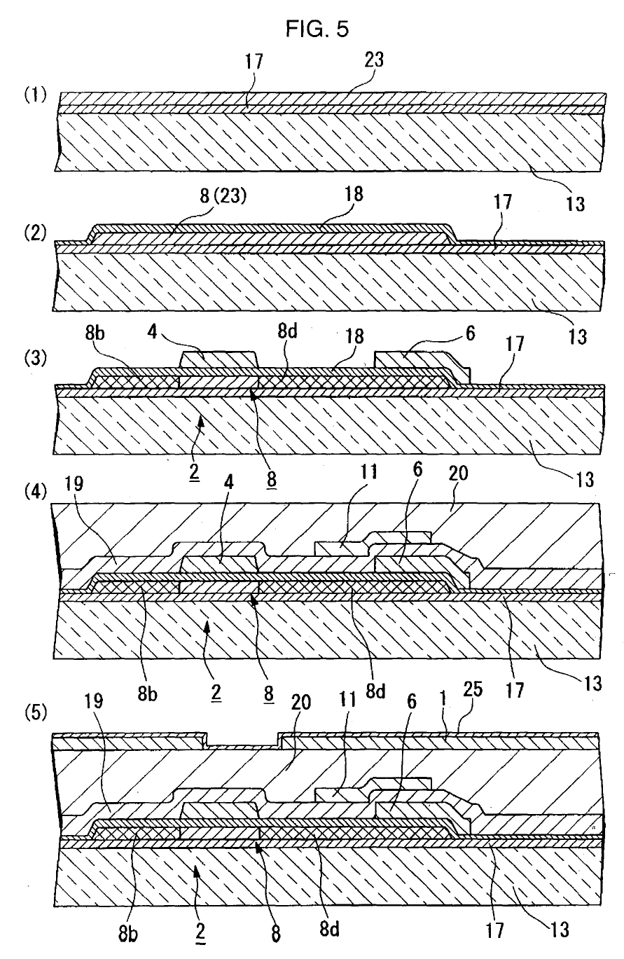

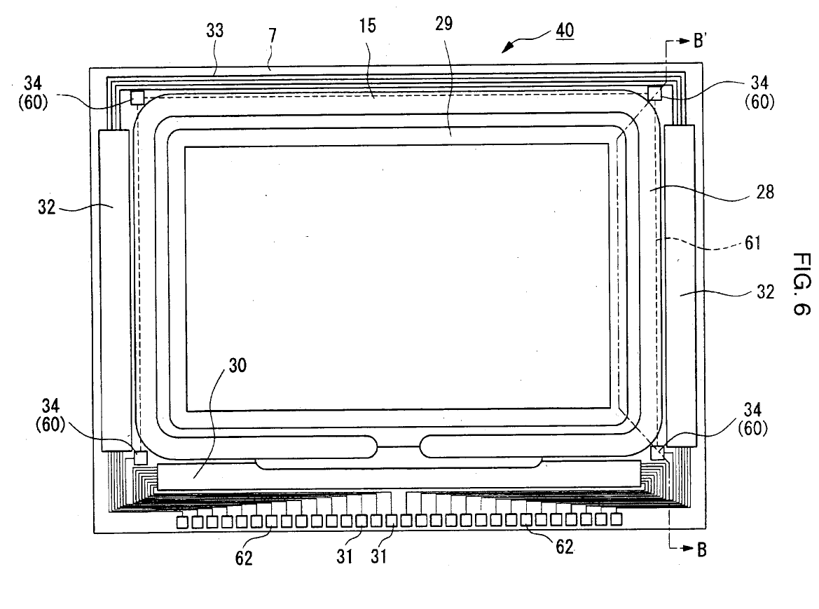

A first embodiment of the present invention will be described with reference to FIGS. 1 to 7. FIG. 1 is an exemplary circuit diagram showing various elements, lines, and the like, in plurality of pixels constituting the image-display region of a liquid crystal device in this embodiment. FIG. 2 is a plan view showing a plurality of adjoining pixels in a TFT array substrate provided with data lines, scanning lines, pixel electrodes, etc. FIG. 3 is a plan view of a counter substrate provided with a color filter. FIG. 4 is a sectional view taken along the line A-A′ of FIGS. 2 and 3. FIGS. 5(1) to (5) are cross sectional views illustrating fabrication steps of a TFT array substrate. FIG. 6 is a plan view showing the overall structure of a liquid crystal device.

Additionally, in order to make the individual layers and individual elements recognizable in the drawings, the scales for two dimensions, thickness, etc., are appropriately changed for each layer or each element.

As shown in FIG. 1, in the liquid crystal device in this embodiment, with respect to a plurality of pixels formed in a matrix to constitute the image display region, a plurality of pixel electrodes 1 and a plurality of TFTs 2 for controlling the pixel electrodes 1 are formed in a matrix. Data lines 3 for supplying image signals are electrically connected to the source regions of the TFTs 2. Image signals S1, S2, . . . , Sn to be written into the data lines 3 may be supplied in this order and line sequence, or may be supplied to each group including a plurality of adjoining data lines 3. Scanning lines 4 are electrically connected to the gate electrodes of the TFTs 2, and scanning signals G1, G2, . . . , Gm are supplied in a pulsed form in line sequence to the scanning lines 4 with predetermined timing. The pixel electrodes 1 are electrically connected to the drain regions of the TFTs 2, and by tuning, on the TFTs 2, which are switching elements, for a predetermined period, the image signals S1, S2, . . . , Sn supplied from the data lines 3 are written with predetermined timing.

The image signals at a predetermined level written into the liquid crystal through the pixel electrodes 1 are held between the liquid crystal and a counter electrode (described below) formed on a counter substrate (described below) for a predetermined period. In order to avoid the leakage of the held image signals, storage capacitors 5 are added in parallel to liquid crystal capacitors formed between the pixel electrodes 1 and the counter electrode. A capacitor line 6 which serves as an upper electrode of the storage capacitor 5.

As shown in FIG. 2, on a TFT array substrate 7 which is one of the substrates in the liquid crystal device, a plurality of pixel electrodes 1 (outlined by broken lines) are arrayed in a matrix, data lines 3 (outlined by double-dotted chain lines) are provided along the sides of the pixel electrodes 1 extending vertically in the drawing, and scanning lines 4 and capacitor lines 6 (both outlined by solid lines) are provided along the sides extending horizontally in the drawing. When the liquid crystal device is a transmissive liquid crystal device, the pixel electrode 1 is composed of a transparent conductive film, such as an indium tin oxide (ITO) film. When the liquid crystal device is a reflective liquid crystal device, the pixel electrode 1 is composed of a metal thin film, such as an aluminum (Al) film. When the liquid crystal device is a transflective liquid crystal device, the pixel electrode 1 is, for example, composed of a laminate including a transparent conductive film and a metal thin film.

In this embodiment, a semiconductor layer 8 composed of a polysilicon film (outlined by chain dotted line) is formed in a U shape in the vicinity of each intersection between the data lines 3 and the scanning lines 4, and one end of a U-shaped section 8a extends toward the adjacent data line 3 (rightward in the drawing) and in a direction along the data line 3 (upward in the drawing). Contact holes 9 and 10 are formed on both sides of the U-shaped section 8a of the semiconductor layer 8. The contact hole 9 is a source contact hole which electrically connects the data line 3 to the source region of the semiconductor layer 8, and the contact hole 10 is a drain contact hole which electrically connects a drain electrode 11 (outlined by double-dotted chain lines) to the drain region of the semiconductor layer 8. A pixel contact hole 12 which electrically connects the drain electrode 11 to the pixel electrode 1 is formed on an end of the drain electrode 11 opposite to the end provided with the drain contact hole 10.

In the TFT 2 in this embodiment, the U-shaped section 8a of the semiconductor layer 8 intersects with the scanning line 4, and since the semiconductor layer 8 and the scanning line 4 intersect with each other at two sections, a so-called dual-gate-type TFT in which two gates are provided on one semiconductor layer is formed. The capacitor line 6 extends along the scanning line 4 so as to pass through the pixels aligning in the horizontal direction in the drawing, and a branched portion 6a extends along the data line 3 in the vertical direction in the drawing. Therefore, a storage capacitor 5 is formed by the semiconductor layer 8 and the capacitor line 6 both of which extend along the data line 3.

On the other hand, as shown in FIG. 3, on a counter substrate 15, color layers 22 corresponding to the three primary colors, red (R), green (G), and blue (B), constituting a color filter are provided so as to correspond to the individual pixel regions of the TFT array substrate 7, and a first light-shielding film (black matrix) 21 for shielding the boundaries of the color layers 22 from light is also provided in a grid pattern.

As shown in FIG. 4, the liquid crystal device in this embodiment can include a pair of transparent substrates 13 and 14 corresponding to the TFT array substrate 7 and the counter substrate 15 facing the TFT array substrate 7, respectively. A liquid crystal 16 is interposed between the substrates 7 and 15. The transparent substrates 13 and 14 are, for example, composed of glass substrates or quartz substrates.

As shown in FIG. 4, an underlying insulating film 17 is formed on the TFT array substrate 7, the semiconductor layer 8, for example, composed of a polysilicon film with a thickness of approximately 30 to 100 nm, is formed on the underlying insulating film 17, and the insulating thin film 18 serving as a gate insulating film is formed with a thickness of approximately 30 to 150 nm so as to cover the semiconductor layer 8. The TFT 2 which switches on and off each pixel electrode 1 is disposed on the underlying insulating film 17. The TFT 2 is provided with the scanning line 4 composed of a metal, such as tantalum or aluminum, a channel region 8c of the semiconductor layer 8 in which a channel is formed by an electric field from the scanning line 4, the insulating thin film 18 serving as a gate insulating film for insulating the scanning line 4 from the semiconductor layer 8, the data line 3 (not shown in FIG. 4) composed of a metal, such as aluminum, and a source region 8b and a drain region 8d of the semiconductor layer 8.

A first interlayer insulating film 19 provided with the source contact hole 9 (not shown ill FIG. 4) leading to the source region 8b and the drain contact hole 10 (not shown in FIG. 4) leading to the drain region 8d is formed on the TFT away substrate 7 including the scanning line 4 and the insulating thin film 18. In other words, the data line 3 is electrically connected to the source region 8b via the source contact hole 9 passing through the first interlayer insulating film 19.

Furthermore, the drain electrode 11, composed of the same metal as that for the layer of the data line 3, is formed on the first interlayer insulating film 19, and a second interlayer insulating film 20 provided with the pixel contact hole 12 (not shown in FIG. 4) leading to the drain electrode 11 is formed thereon. In other words, the pixel electrode 1 is electrically connected to the drain region 8d of the semiconductor layer 8 through the drain electrode 11.

The storage capacitor 5 is formed on the side of the TFT 2 shown in FIG. 4. In the storage capacitor 5, the underlying insulating film 17 is placed on the transparent substrate 13, the semiconductor layer 8, doped with an impurity which is integrally molded with the semiconductor layer 8 of the TFT 2, is placed on the underlying insulating film 17, and the insulating thin film 18 is formed over the entire surface thereof so as to cover the semiconductor layer 8. A capacitor line 6, composed of the same metal as that for the layer of the scanning line 4, is formed on the insulating thin film 18, and the first interlayer insulating film 19 is formed over the entire surface thereof.

The second interlayer insulating film 20 is used as a planarizing film, and can be formed of, for example, an acrylic film which is a type of a resin film with high flatness, with a thickness of approximately 2 μm. The pixel electrode 1 is formed on the surface of the second interlayer insulating film 20, and an alignment film 25 composed of a polyimide or the like is placed on the uppermost surface of the TFT array substrate 7 in contact with the liquid crystal 16.

On the other hand, with respect to the counter substrate 15, a first light-shielding film 21 composed of a metal film, such as a chromium film, a resin black resist, or the like, is formed on the transparent substrate 14, and the color layers 22 are formed on the first light-shielding film 21. The counter electrode 24 composed of a transparent conductive film, such as an ITO film, similar to that for the pixel electrode 1, and an alignment film 26 are formed in that order over the entire surface of the substrate.

Next, a process for fabricating a liquid crystal device having the structure described above will be described with reference to FIG. 5.

FIGS. 5(1) to (5) are sectional views illustrating fabrication steps of the TFT array substrate 7.

First, as shown in step (1) in FIG. 5, the underlying insulating film 17 is formed on the transparent substrate 13, such as a glass substrate, and an amorphous silicon layer is deposited thereon. The amorphous silicon layer is then subjected to heat treatment, such as laser annealing treatment, so that the amorphous silicon layer is recrystallized to thereby form a crystalline polysilicon layer 23 with a thickness of approximately 30 to 100 nm.

Next, as shown in step (2) in FIG. 5, the polysilicon layer 23 thus formed is patterned so as to have the pattern of the semiconductor layer 8 described above, and the insulating thin film 18 serving as a gate insulating film is formed thereon, for example, with a thickness of approximately 30 to 150 nm.

The display region, excluding the portions for forming a connecting section between the TFT 2 and the storage capacitor 5 and for forming a lower electrode of the storage capacitor 5 is masked with a resist, such as a polyimide, so that the polysilicon layer can be doped, for example, with PH3/H2 ions as donors through the insulating thin film. The ions are implanted, for example, with a 3¹P ion dose of approximately 3×10¹⁴ to 5×10¹⁴ ions/cm² and an accelerating energy of approximately 80 keV.

After the resist is removed, as shown in step (3) in FIG. 5, the scanning line 4 and the capacitor line 6 are formed on the insulating thin film 18. In order to form the scanning line 4, and the like, after a metal, such as tantalum or aluminum, is sputtered or vacuum-deposited, a resist pattern for the scanning line 4, etc., is formed, etching is performed using the resist pattern as a mask, and the resist pattern is removed. After the scanning line 4 and the capacitor line 6 are thus formed, a resist pattern which covers the storage capacitor 5 is formed, and PH3/H2 ions are implanted. The ions are implanted, for example, with a 3¹P ion dose of approximately 5×10¹⁴ to 7×10¹⁴ ions/cm² and an accelerating energy of approximately 80 keV. By step (3) described above, the source region 8b and the drain region 8d of the TFT 2 are formed.

After the resist pattern is removed, as shown in step (4) in FIG. 5, the first interlayer insulating film 19 is deposited, and openings for forming the source contact hole 9 and the drain contact hole 10 (both not shown in FIG. 5) are made at the appropriate positions. A metal, such as aluminum, is then sputtered or vapor-deposited, a resist pattern in the shapes of the date line 3 and the drain electrode 11 is formed, and the data line 3 (not shown in the drawing) and the drain electrode 11 are formed by etching using the resist pattern as a mask. The second interlayer insulating film 20 is deposited thereon, and an opening corresponding to the pixel contact hole 12 is made at the appropriate position.

Next, as shown in step (5) in FIG. 5, a transparent conductive thin film composed of ITO or the like with a thickness of approximately 50 to 200 nm is formed, and patterned to thereby form the pixel electrode 1. Finally, the alignment film 25 is formed all over the surface. The TFT array substrate 7 in this embodiment is thereby completed. The above described fabrication process is for a transmissive liquid crystal device. In the case of a reflective liquid crystal device, the pixel electrode 1 is composed of a metal thin film, such thin film, and in the case of a transflective liquid crystal device, the pixel or example, composed of a laminate including a transparent conductive film film.

With respect to the counter substrate 15 shown in FIG. 4, although the fabrication process is not shown in the drawing, the transparent substrate 14, such as a glass substrate, is prepared first. The first light-shielding film 21 and a second light-shielding film 29 as a frame (refer to FIG. 6), which will be described below, are formed, for example, by sputtering metallic chromium, followed by photolithography and etching. Additionally, the light-shielding films 21 and 29 may be composed of a metal material, such as chromium (Cr), nickel (Ni), or aluminum (Al), or a resin black in which carbon or titanium is dispersed in a photoresist.

Next, after the color layers 22 constituting a color filter can be formed by a known method, such as dyeing, a pigment dispersion method, or printing. Further, a counter electrode 24 can be formed over the entire surface of the counter substrate 15 by depositing a transparent conductive thin film, such as an ITO film, by sputtering with a thickness of approximately 50 to 200 nm.

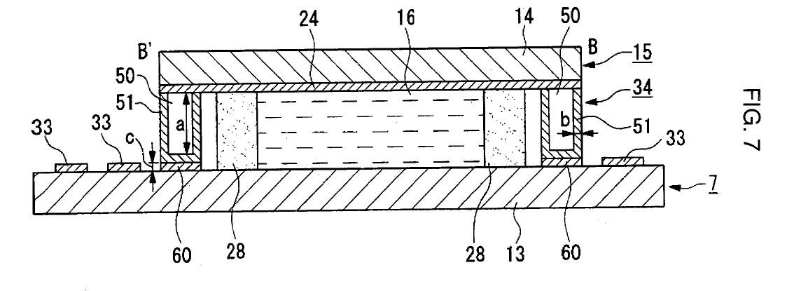

Furthermore, protrusions 50 are formed by applying an organic resin material, such as an acrylic resin and a polyimide resin, using a spin coater or the like with a thickness of approximately 3 μm, followed by patterning. The surfaces of the protrusions 50 are coated with conductive layers 51 (refer to FIGS. 6 and 7 which will be described below) to produce intersubstrate conductive parts 34. The alignment film 26 is then formed over the entire surface of the counter electrode 24. Since such protrusions 50 are formed by applying an organic material, such as an acrylic resin, onto the counter substrate 15, the protrusions 50 can be easily formed only with a slight change in the ordinary fabrication process.

Additionally, the protrusions 50 may be integrally molded when the transparent substrate 14 is molded, and thereby the fabrication process is simplified. When the protrusions 50 are composed of an inorganic material, such as a silicon oxide film or silicon nitride film, it is possible to easily and accurately form, by using a common film-forming technique in the semiconductor fabrication step, the protrusions 50 with a desired thickness in a desired shape. Furthermore, the protrusions 50 may be formed by laminating a plurality of film materials, if appropriate.

The intersubstrate conductive portion 34 serves to maintain electrical conduction between the TFT array substrate 7 and the counter substrate 15, and by bringing the intersubstrate conductive portion 34 into contact with a common electrode 60 (refer to FIGS. 6 and 7) provided on the TFT array substrate 7, the counter electrode 24 and the common electrode 60 are electrically connected to each other. At least one common electrode 60 is provided on the TFT array substrate 7 so that a voltage is applied to the counter electrode 24 without delay in response to input signals and uniformly to any part of the counter substrate 15. The individual common electrodes 60 are connected to each other by a common line 61. It should be understood that the material for the conductive layer 51 of the intersubstrate conductive portion 34 is not particularly limited as long as it is conductive, and may include a metal, such as silver, copper, nickel, or aluminum, or a transparent conductive film, such as an ITO film. Such a conductive layer 51 can be easily formed on the surface of the protrusion 50 by any one of various film-forming techniques, such as vacuum deposition. In such a case, the surface of the substrate other than the protrusion 50 on which the conductive layer 51 is to be formed may be masked by applying a photosensitive resin or the like, and after the conductive layer 51 is formed, the masking material is removed.

By setting the sum (a+b+c) of the height a of the protrusion 50, the thickness b of the conductive layer 51, and the thickness c of the common electrode 60, i.e., the sum of the height of the intersubstrate conductive part 34 from the substrate and the thickness of the common electrode 60, to be equal to the distance between the substrates of the liquid crystal device, the intersubstrate conductive part 34 has the function to maintain a predetermined cell gap and can be used as a spacer. For example, if the cell gap is 3.2 μm, the thickness of the common electrode is 0.2 μm, and the height of the protrusion is 3 μm, the thickness of the conductive layer can be set to 0.2 μm.

Although the number of intersubstrate conductive parts 34 is not particularly limited, preferably, at least one intersubstrate conductive part is placed at each corner of the image-display region in view of more uniform and prompt response.

Finally, the TFT array substrate 7 and the counter substrate 15 on which the individual layers have been formed as described above are opposed and bonded to each other by a sealant to produce an empty panel. By injecting the liquid crystal 16 into the empty panel, the liquid crystal device in this embodiment is completed.

Next, the overall structure of a liquid crystal device 40 will be described with reference to FIG. 6. Referring to FIG. 6, a sealant 28 is provided on the TFT array substrate 7 along the edge thereof, and the second light-shielding film 29 is provided as a frame inside and parallel to the sealant 28. In the region outside the sealant 28, a data line drive circuit 30 and external circuit-connecting terminals 31 are provided along one side of the TFT array substrate 7, and scanning line drive circuits 32 are provided along two sides adjacent to the side described above. If delays in supplying scanning signals to the scanning lines 4 cause no problem, the scanning line drive circuit 32 may be formed on only one side. Additionally, data line drive circuits 30 may be placed along the image-display region on both sides thereof. For example, image signals may be supplied from a data line drive circuit placed along one side of the image-display region to the data lines 3 in odd columns, and image signals may be supplied from a data line drive circuit placed along the opposite side of the image-display region to the data lines 3 in even columns. If the data lines 3 are driven like a comb, as described above, since the area that the data line drive circuits occupy is expanded, a complex circuit may be configured. Furthermore, on the remaining side of the TFT array substrate 7, a plurality of wire lines 33 for connecting the scanning line drive circuits 32 provided on both sides of the image-display region are provided. The counter substrate 15 which has substantially the same outline as that of the sealant 28 is fixed to the TFT array substrate 7 by the sealant 28.

The common electrode 60 is provided on at least one corner of the TFT array substrate 7 so that a voltage can be applied to the counter electrode 24 of the counter substrate 15. The intersubstrate conductive parts 34 which enable electrical conduction between the substrates are provided on the counter substrate 15 at the positions facing the common electrodes 60 and are connected to the common electrodes 60. The individual common electrodes 60 are connected to each other by common wire lines 61 shown by broken lines and solid lines in FIG. 6, and are connected to common terminals 62. A voltage can be uniformly applied to the counter electrode 24 without delay in response to input from the common terminals 62. Any number of common electrodes 60 is acceptable as long as uniform voltage application to the counter substrate 24 without delay is enabled.

FIG. 7 is a schematic sectional view of the liquid crystal device 1 taken along the line B-B′ of FIG. 6, and with reference to FIG. 7, the intersubstrate conductive part 34 will be described in more detail. FIG. 7 schematically shows the state of connection between the TFT array substrate 7 and the counter substrate 15, and in FIG. 7, the elements not directly related to the connection between the substrates, for example, the switching elements, such as TFTs, and the alignment films, which are explained in detail in FIGS. 1 to 6, are omitted. Referring to FIG. 7, the TFT array substrate 7 and the counter substrate 15 are fixed to each other by the sealant 28 which seals the liquid crystal 16, and electrical conduction is maintained by the intersubstrate conductive parts 34. The intersubstrate conductive part 34 is provided on the counter substrate 15 so as to be brought into contact with the common electrode 60 provided on the TFT array substrate 7. The sum of the height a of the protrusion 50, the thickness b of the conductive layer 51, and the thickness c of the common electrode 60 is equal to the cell gap of the liquid crystal device. That is, the intersubstrate conductive parts 34 function as spacers.

In accordance with the intersubstrate conductive parts 34 having the structure described above, the space required for forming the intersubstrate conductive parts 34 can be decreased compared to the conductive parts composed of the conventional conductive paste, and thus the frame can be narrowed. Since the conductive layer 51 is composed of a uniform film material, the same conductivity is exhibited at any part thereof, and therefore, electrical conduction between the substrates can be maintained with a predetermined resistance. Furthermore, by placing a plurality of intersubstrate conductive parts having a constant conductivity, it is possible to uniformly apply a voltage without delay to the counter substrate 15, and thus a clearer image can be displayed.

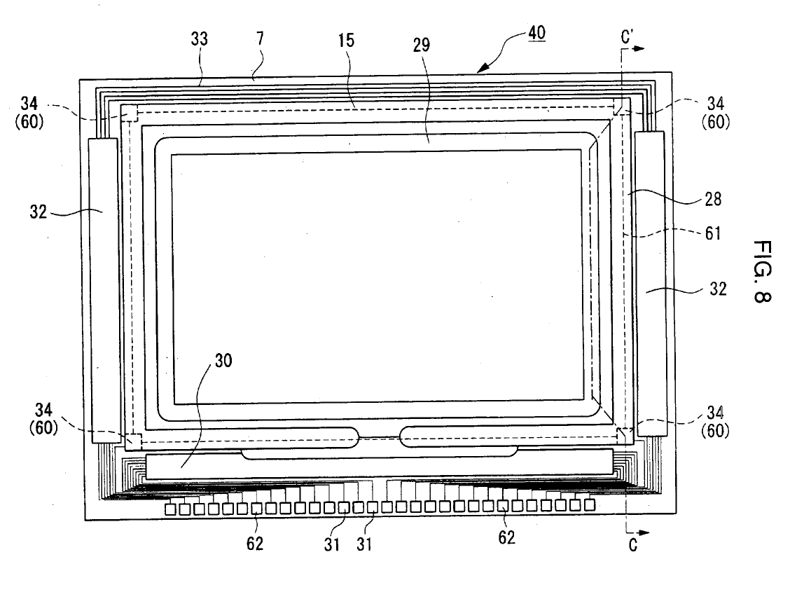

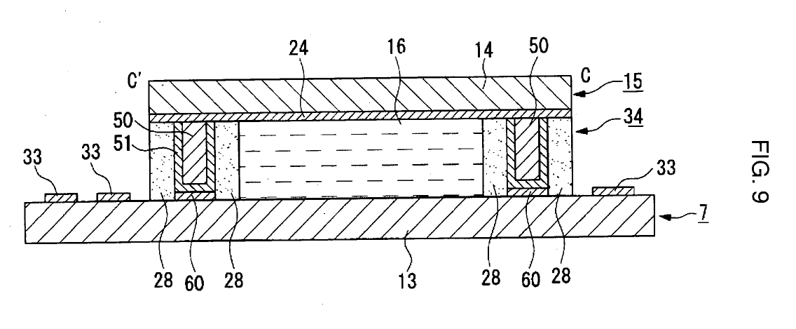

A second embodiment of the present invention will be described with reference to FIGS. 8 and 9. FIG. 9 is a sectional view of a liquid crystal device taken along the dashed line C-C′ of FIG. 8.

The liquid crystal device in this embodiment differs from the liquid crystal device in the first embodiment in that the intersubstrate conductive part 34 is placed inside the sealant 28 which seals the liquid crystal 16 between the substrates.

In such a construction, the contact bonding density between the intersubstrate conductive part 34 and the common electrode 60 is improved, and the mechanical strength is increased. A change in the resistance of the intersubstrate conductive part 34 due to a change in the contact bonding state can also be decreased. Consequently, more reliable electrical conduction can be maintained between the substrates.

In such a construction, since the conductive layer 51 is not directly exposed to air, an increase in the resistance of the conductive layer 51 due to oxidation, etc., can be prevented, and thus a liquid crystal device with more satisfactory durability can be produced.

Furthermore, in such a construction, since the intersubstrate conductive part 34 is contained in the space where the sealant 28 is placed, the fame can be further narrowed. In particular, when the intersubstrate conductive part 34 is also used as a spacer for maintaining the cell gap, this advantage becomes remarkable.

Specific examples of electronic apparatuses each provided with a liquid crystal device of the present invention will be described below.

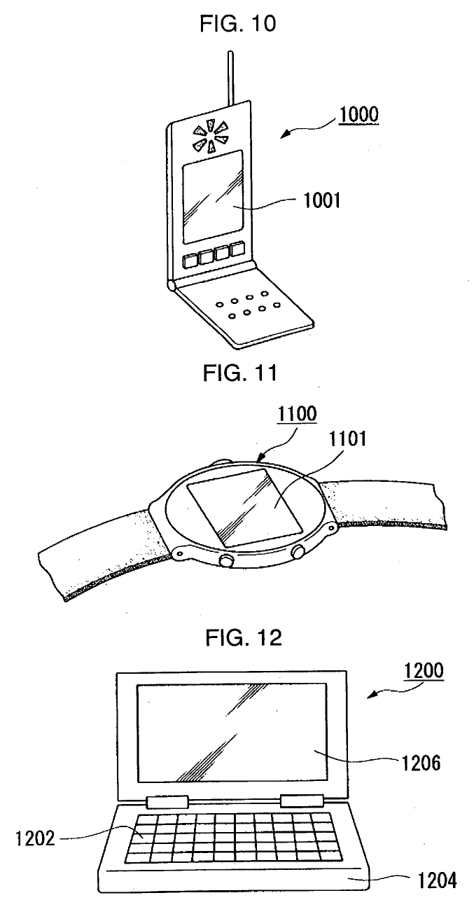

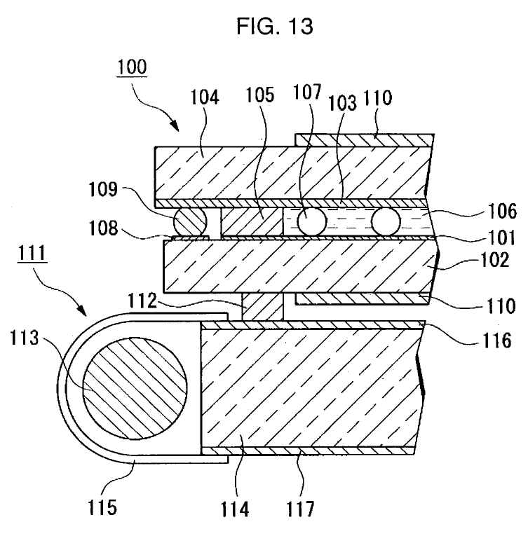

FIG. 10 is a perspective view showing a mobile phone. In FIG. 10, numeral 1000 represents a mobile phone body, and numeral 1001 represents a liquid crystal display region using the liquid crystal device described above.

FIG. 11 is a perspective view showing a wristwatch-type electronic apparatus. In FIG. 11, numeral 1100 represents a watch body, and numeral 1101 represents a liquid crystal display region using the liquid crystal device described above.

FIG. 12 is a perspective view showing a mobile information processor, such as a word processor or a personal computer. In FIG. 12, numeral 1200 represents an information processor, numeral 1202 represents an input part, such as a keyboard, numeral 1204 represents an information processor body, and numeral 1206 represents a liquid crystal display region using the liquid crystal device described above.

In the electronic apparatuses shown in FIGS. 10 to 12, since the liquid crystal display regions using the liquid crystal devices described above are provided, excellent display can be obtained.

It should be understood that the technical field of the present invention is not limited to the embodiments described above, and it is possible to make various modifications within the scope of the present invention. For example, although the protrusion 50 is composed of one thick layer in the first and second embodiments, the protrusion 50 may be composed of a laminate including two or more layers. Although the protrusion 50 is composed of an organic film, such as an acrylic film or polyimide film, in the embodiments described above, instead of the above material, an inorganic film, such as a silicon oxide film or silicon nitride film, may be used. Furthermore, with respect to the shape and position of the protrusion 50, design may be appropriately changed from those shown in the embodiments.

Although an active matrix liquid crystal device using TFTs as switching elements are described in the embodiments, the present invention is also applicable to an active matrix liquid crystal device using thin-film diodes (TFDs) as switching elements, or a passive matrix liquid crystal device. Moreover, the present invention is also applicable to other electro-optical devices, such as electroluminescent displays and plasma displays.

As specifically described above in accordance with the present invention, since the substrate conductive part is formed by applying the conductive layer to the protrusion provided on one of the substrates, stable electrical conduction can be maintained between the substrates, and the space occupied by the intersubstrate conductive part in the electro-optical device can be decreased, and thus the frame can be narrowed.

If the height of the protrusion and the thickness of the conductive layer are set at predetermined values, the cell gap can be controlled simultaneously, and the intersubstrate conductive part can be used as a spacer, and thus the frame can be further narrowed.

Moreover, if the intersubstrate conductive part is placed inside the sealant which seals the liquid crystal, the frame can be further narrowed, the mechanical strength of the intersubstrate conductive part is improved, and the conductive layer is not exposed to air. Therefore, stabler electrical conduction can be maintained between the substrates, and an device having satisfactory durability can be produced.

What is claimed is:

1. An electro-optical device, comprising:
a pair of substrates facing each other;
an electro-optical material disposed therebetween;
a conductive section that is provided on the inner surface of each of the pair of substrates; and
an intersubstrate conductive part including a protrusion coated with a conductive layer that is provided on one of the pair of substrates, the conductive sections of the individual substrates being electrically connected to each other through the intersubstrate conductive part.

2. An electro-optical device, comprising:
a pair of substrates facing each other;
an electro-optical material interposed therebetween;
a conductive section that is provided on the inner surface of each of the pair of substrates; and
a protrusion that is provided on one of the pairs of substrates, the protrusion maintaining a predetermined distance between the pair of substrates, the conductive sections of the individual substrates being electrically connected to each other through an intersubstrate conductive part including the protrusion coated with a conductive layer.

3. The electro-optical device according to claim 1, the protrusion of the intersubstrate conductive part including at least one layer material constituting one of the pair of substrates.

4. The electro-optical device according to claim 1, the protrusion of the intersubstrate conductive part including a resin material.

5. The electro-optical device according to claim 1, the conductive layer of the intersubstrate conductive part including a metal film.

6. The electro-optical device according to claim 1, the conductive layer of the intersubstrate conductive part comprising a transparent conductive film.

7. The electro-optical device according to claim 1, the electro-optical material comprising a liquid crystal.

8. The electro-optical device according to claim 1, the intersubstrate conductive part being provided in a periphery outside the image-display region of each substrate.

9. The electro-optical device according to claim 1, the intersubstrate conductive part being placed inside a sealing section that seals the electro-optical material.

10. A method for fabricating an electro-optical device having an electro-optical material interposed between a pair of substrates facing each other, the method comprising:
forming a protrusion on one of the substrates, and
forming a conductive layer on the protrusion to produce an intersubstrate conductive part.

11. The method for fabricating an electro-optical device according to claim 10, one of the substrates and the protrusion of the intersubstrate conductive part being integrally molded.

12. The method for fabricating an electro-optical device according to claim 10, wherein the protrusion of the intersubstrate conductive part being formed by photolithography.

13. An electronic apparatus comprising the electro-optical device according to claim 1.

14. The electro-optical device according to claim 2, the protrusion of the intersubstrate conductive part including at least one layer material constituting one of the pair of substrates.

15. The electro-optical device according to claim 2, the protrusion of the intersubstrate conductive part including a resin material.

16. The electro-optical device according to claim 2, the conductive layer of the intersubstrate conductive part including a metal film.

17. The electro-optical device according to claim 2, the conductive layer of the intersubstrate conductive part comprising a transparent conductive film.

18. The electro-optical device according to claim 2, the electro-optical material comprising a liquid crystal.

19. The electro-optical device according to claim 2, the intersubstrate conductive part being provided in a periphery outside the image-display region of each substrate.

20. The electro-optical device according to claim 2, the intersubstrate conductive part being placed inside a sealing section that seals the electro-optical material.

21. An electronic apparatus comprising the electro-optical device according to claim 2.
